(19) United States
(12) Patent Application Publication
(10) Pub. No.: US 2005/0248370 A1
(43) Pub. Date: Nov. 10, 2005

(54) DATA TRANSFERRING METHOD

(76) Inventors: Yu-Hsuan Li, Kaohsiung City (TW); Alex Tang, Hsinchu city (TW); Yueh-Hsiu Liu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,921

(22) Filed: Apr. 21, 2005

(30) Foreign Application Priority Data
Apr. 22, 2004 (TW) 93111202

(51) Int. Cl. G01R 19/00

(52) U.S. Cl. 327/58

(57) ABSTRACT

A data transferring method for the input interface of a liquid crystal display. In the conventional reduced swing differential signal (RSDS) data transferring method, a pair of data lines can transmit a single bit of data. Thus, more data line pairs are required to transmit more data bits leading to a rapid increase in spatial occupancy and production cost. The present invention permits more data bits to be transmitted for the same number of data lines by converting DC levels into AC levels. With two DC levels provided by two pairs of data lines, a third bit of data can be transmitted. Similarly, with four DC levels provided by four pairs of data lines, seven bit data can be transmitted. Since more data can be transmitted with a given set of data lines, space and production cost is saved.

### CROSS-REFERENCE TO RELATED APPLICATION

This application claims the priority benefit of Taiwan application serial no. 93111202, filed on Apr. 22, 2004. All disclosure of the Taiwan application is incorporated herein by reference.

### BACKGROUND OF THE INVENTION

1. Field of the Invention

The present invention relates to a data transferring method. More particularly, the present invention relates to a differential signal data transferring method.

2. Description of the Related Art

In recent years, liquid crystal displays have gradually become mainstream display products. Liquid crystal display panel not only is light and slim, but can also operate at a low voltage at a low power rating free from any hazardous radiation emission. Most of all, the liquid crystal display can have a display area that spans a large range. With all these advantages, many types of portable electronic devices including notebook computers, mobile phones, personal digital assistants (PDA) have or must have a liquid crystal display screen. Because of its immense popularity, an efficient means of transferring data to a liquid crystal display device is increasingly important.

In a conventional thin film transistor liquid crystal display, reduced swing differential signal (RSDS) data transferring method is often employed. FIG. 1 is diagram showing the transmission of data using a conventional RSDS method. As shown in FIG. 1, a single pair of data lines can only transmit a single bit of data. For example, a pair of data line (D00P-D00N) can transmit a single bit of data, two pairs of data lines (D00P-D00N) and (D01P-D01N) can transmit two bits of data while three pairs of data lines (D00P-D00N), (D01P-D01N) and (D02P-D02N) can transmit three bits of data. In other words, at least N pairs of data lines are required to transmit N bits of data. As the number of data lines increases due to an increase in data transmission, both the spatial occupancy and the production cost of the data lines will increase.

### SUMMARY OF THE INVENTION

Accordingly, at least one objective of the present invention is to provide a method of transferring data that utilizes the signals provided by two pairs of data transmission lines, that is, the DC voltage levels for transmitting two data bits, to generate an additional data bit. The method can also be applied to a system with a plurality of data transmission pairs such that the transmitted voltage levels of every two data bits can have a swing to transmit an extra data bit. Therefore, more data bits can be transmitted using limited available resources.

To achieve these and other advantages and in accordance with the purpose of the invention, as embodied and broadly described herein, the invention provides a method of transferring data that utilizes a differential signal transmission structure. The data transferring method includes selecting a first DC voltage level of a first pair of differential signal source to serve as a first differential signal. The first pair of differential signal source generates a first data bit. Thereafter, a second DC voltage level of a second pair of differential signal source is selected to serve as a second differential signal. The second pair of differential signal source generates a second data bit. Finally, the first differential signal and the second differential signal together generate a third data bit.

According to one embodiment of the aforementioned data transferring method, the third data bit has the logic level ‘0’ when the first DC voltage level is higher than the second DC voltage level. The third data bit has the logic level ‘1’ when the first DC voltage level is lower than the second DC voltage level.

The present invention also provides an alternative method of transferring data that utilizes a differential signal transmission structure. The differential signal transmission structure comprises a plurality of pairs of differential signal sources. The data transferring method includes generating extra pairs of differential signal sources according to the two DC voltage levels provided by every two pairs of differential signal sources. Thereafter, the extra pairs of differential signal sources are utilized to generate corresponding data bits.

According to one embodiment of the aforementioned data transferring method, the method further comprises selecting the DC voltage levels provided by every two pairs of extra differential signal sources to generate additional data bits.

The present invention also provides another method of transferring data that utilizes a differential signal transmission structure. The differential signal transmission structure comprises a plurality of pairs of differential signal sources. The data transferring method includes selecting a first DC voltage level of a first pair of differential signal sources to serve as a first differential signal. The first pair of differential signal sources generates a first bit. Thereafter, a second DC voltage level of a second pair of differential signal sources is selected to serve as a second differential signal. The second pair of differential signal sources generates a second bit. A third DC voltage level of a third pair of differential signal sources is selected to serve as a third differential signal. The third pair of differential signal sources generates a third bit. A fourth DC voltage level of a fourth pair of differential signal sources is selected to serve as a fourth differential signal. The fourth pair of differential signal sources generates a fourth bit. A fifth data bit is produced when the first differential signal and the second differential signal cross over each other. Similarly, a sixth data bit is produced when the third differential signal and the fourth differential signal cross over each other. Finally, a seventh data bit is produced when a fifth DC voltage level produced by the first differential signal and the second differential signal crosses with a sixth DC voltage level produced by the third differential signal and the fourth differential signal.

According to one embodiment of the aforementioned data transferring method, the fifth data bit has a logic level ‘0’ when the first DC voltage level is higher than the second DC voltage level. The fifth data bit has a logic level ‘1’ when the first DC voltage level is lower than the second DC voltage level. The sixth data bit has a logic level ‘0’ when the third DC voltage level is higher than the fourth DC voltage level. The sixth data bit has a logic level ‘1’ when the third DC voltage level is lower than the fourth DC voltage level. The seventh data bit has a logic level ‘0’ when the fifth DC voltage level is higher than the sixth DC voltage level. The seventh data bit has a logic level ‘1’ when the fifth DC voltage level is lower than the sixth DC voltage level.

Because DC voltage levels are transformed into AC levels in the present invention, more data bits can be transmitted through a given set of data lines. Without the limitation of transmitting one data bit per data line pair in the conventional RSDS data transfer method, the number data lines and the space required to accommodate the data lines can be reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is diagram showing the transmission of data using a conventional RSDS method.

FIG. 2 is a timing diagram showing the DC and AC voltage levels during data transmission using a data transferring method according to one preferred embodiment of the present invention.

FIG. 3 is a timing diagram showing the DC and AC voltage levels during data transmission using a data transferring method according to FIG. 2 and the voltage level produced by the three data bits D0, D1 and D2.

FIG. 4 a timing diagram showing the DC and AC voltage levels during data transmission using a data transferring method according to another preferred embodiment of the present invention.

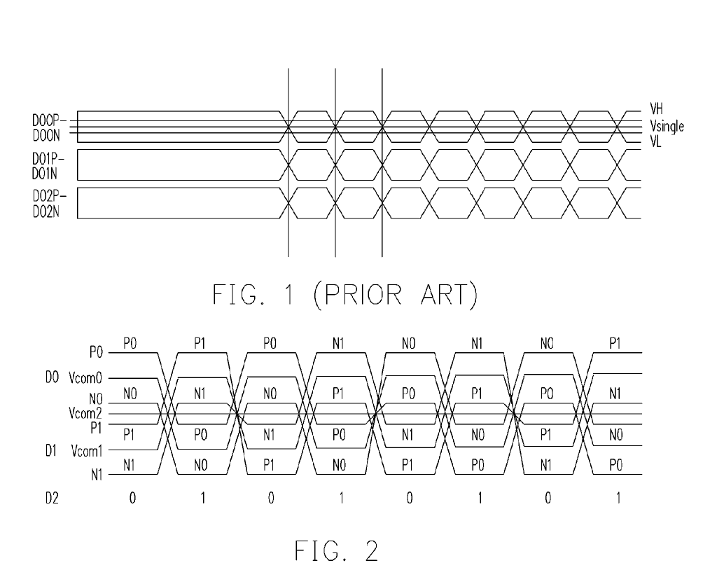

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the present invention, the number of data bits that can be transmitted through an existing set of data lines is increased by converting DC voltage levels into AC voltage levels. In other words, more data lines are saved when the amount of data that needs to be transmitted is increased. Thus, fewer data lines and less space for accommodating the data lines is required. Hence, overall fabrication cost of a transmission interface can be reduced.

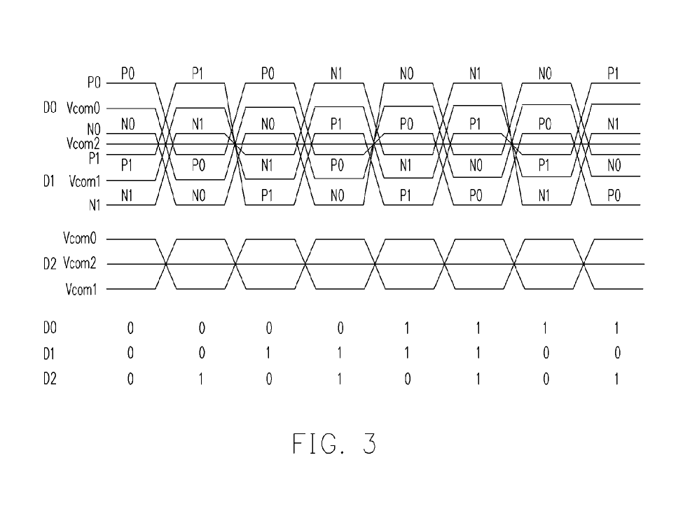

FIG. 2 is a timing diagram showing the DC and AC voltage levels during data transmission using a data transferring method according to one preferred embodiment of the present invention. As shown in FIG. 2, a swing in the signal voltage levels for transmitting two bits of data in the original reduced swing differential signal (RSDS) transmission method can be introduced to produce three data bits. In other words, three data bits can be transmitted using the existing differential signals for transmitting two data bits. Furthermore, the differential signal circuit for transmitting the two data bits has altogether 8 different states.

The originally transmitted data bits D0 and D1 have two pairs of data lines between voltage levels P0 and N0 as well as P1 and N1 to serve as differential signal sources. The DC voltage level of data bits D0 and D1 are Vcom0 and Vcom1 respectively.

In the present embodiment, aside from the original two data bits D0 and D1, the voltage levels P0/N0 and P1/N1 of the two pairs of data transmission lines can be used to generate another data bit D2. The data differential signal of the data bit D2 is generated by the crossing over and the swing between the DC voltage levels Vcom0 and Vcom1 of the data bits D0 and D1. The new DC voltage level for the data bit D2 is Vcom2.

FIG. 3 is a timing diagram showing the DC and AC voltage levels during data transmission using a data transferring method according to FIG. 2 and the voltage level produced by the three data bits D0, D1 and D2. The new data bit D2 is produced by converting the DC level of the data bits D0 and D1 into AC levels. Therefore, the original DC voltage level Vcom0 of the data bit D0 is a differential signal P2 with respect to the data bit D2 and the original DC voltage level Vcom1 of the data bit D1 is another differential signal N2 with respect to the data bit D2. Vcom0 and Vcom1 are a set of new differential signals for the data bit D2 such that the DC voltage level of D2 is Vcom2.

In table 1, the 8 different states produced by the three data bits generated through two pairs of data lines are displayed. When the differential signal P0 of the data bit D0 is greater than N0 or P0 is greater than the DC voltage level Vcom0 of the data bit D0, the data line D0 outputs a data bit ‘0’. Otherwise, the data line D0 outputs a data bit ‘1’. When the differential signal P1 of the data bit D1 is greater than N1 or P1 is greater than the DC voltage level Vcom1 of the data bit D1, the data line D1 outputs a data bit ‘0’. Otherwise, the data line D0 outputs a data bit ‘1’. The output from the data line D2 is determined by the DC voltage level of the data bit D0 or D1. When Vcom0 is greater than Vcom2 or Vcom0 is greater than Vcom1, the data line D2 outputs a data bit ‘0’. Otherwise, the data line D2 outputs a data bit ‘1’.

TABLE 1
(V1 > V2 > V3 > V4)

| D0 | D1 | D2 | V1 | V2 | V3 | V4 |
|---|---|---|---|---|---|---|
| 0 | 0 | 0 | P0 | N0 | P1 | N1 |
| 0 | 0 | 1 | P1 | N1 | P0 | N0 |
| 0 | 1 | 0 | P0 | N0 | N1 | P1 |
| 0 | 1 | 1 | N1 | P1 | P0 | N0 |
| 1 | 1 | 0 | N0 | P0 | N1 | P1 |
| 1 | 1 | 1 | N1 | P1 | N0 | P0 |
| 1 | 0 | 0 | N0 | P0 | P1 | N1 |
| 1 | 0 | 1 | P1 | N1 | N0 | P0 |

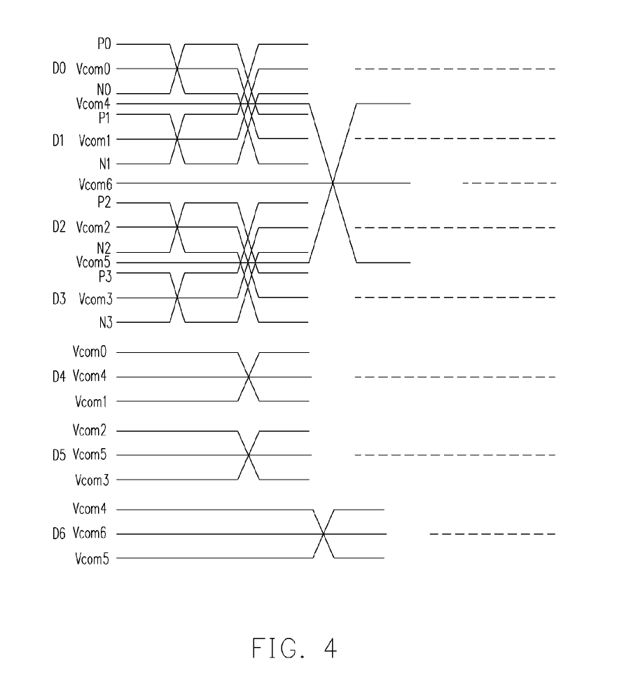

According to the principles of the aforementioned data transferring method, every two pairs of data transmission lines, that is, the signaling voltages for transmitting two data bits, generate an extra data bit. The method can also be applied to a system with a plurality of data transmission pairs such that the transmitted voltage levels of every two data bits can have a swing to transmit an extra data bit. Therefore, more data bits can be transmitted using limited available resources. For example, if a data transmission interface has four pairs of data transmission lines, that means, four pairs of different differential signals, the four DC voltage levels can swing out seven sets of differential signals to produce a total of 128 states. FIG. 4 a timing diagram showing the DC and AC voltage levels during data transmission using a data transferring method according to another preferred embodiment of the present invention.

As shown in FIG. 4, there are four pairs of original data lines for transmitting four data bits D0, D1, D2 and D3 and their voltage levels P0 and N0, P1 and N1, P2 and N2 and P3 and N3 serve as differential signal sources. The DC voltage level of the data bits D0, D1, D2 and D3 are Vcom0, Vcom1, Vcom2 and Vcom3 respectively. According to the principles of data transferring method in the present invention, every two differential signal sources is able to generate an additional data bit. Hence, the four data bits D0, D1, D2 and D3 are capable of producing three additional data bits D4, D5 and D6. As shown in FIG. 4, the DC voltage levels Vcom0 and Vcom1 of the data bits D0 and D1 may serve as the two differential signal sources for producing the data bit D4. Similarly, the DC voltage levels Vcom2 and Vcom3 of the data bits D2 and D3 may serve as the two differential signal sources for producing the data bit D5. The DC voltage levels Vcom4 and Vcom5 of the newly introduced data bits D4 and D5 may serve as two differential signal sources for producing the data bit D6. Accordingly, aside from transmitting four data bits D0, D1, D2 and D3, the data transmission method of the present invention also permits the transmission of extra data bits D4, D5 and D6. In other words, altogether seven data bits are transmitted through the four pairs of data transmission lines.

Accordingly, the present invention is able to remove the constraint of at most one data bit per data line pair using the conventional data transmission method. Hence, the N pairs of data lines with each having differential signals P and N and a DC voltage level Vcom can altogether generate 2N-1 data bits through voltage level variations so that more data bits can be transmitted through an existing set of data lines. As the number of data lines increases due to an increase in data transmission, both the spatial occupancy and the production cost of the data lines will be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of transferring data through a differential signal data transmission system, comprising the steps of:
selecting a first DC voltage level of a first pair of differential signal sources to serve as a first differential signal, wherein the first pair of differential signal sources generates a first data bit;
selecting a second DC voltage level of a second pair of differential signal sources to serve as a second differential signal, wherein the second pair of differential signal sources generate a second data bit; and
generating a third data bit according to the first differential signal and the second differential signal.

2. The method of claim 1, wherein the third data bit is set to a logic level ‘0’ when the first DC voltage level is higher than the second DC voltage level and the third data bit is set to a logic level ‘1’ when the first DC voltage level is lower than the second DC voltage level.

3. A method of transferring data through a differential signal transmission system, wherein the differential signal transmission structure comprises a plurality of pairs of differential signal sources, comprising the steps of:
generating a plurality of additional pairs of differential signal sources according to the two DC voltage levels of every pair of differential signal sources and transmitting a plurality of corresponding pairs of data bits according to the additional pairs of differential signal sources.

4. The method of claim 3, wherein the method further comprises selecting the DC voltage levels of every two pairs of differential signal sources from the additional pairs of differential signal sources to generate extra data bits.

5. A method of transferring data through a differential signal transmission system, wherein the differential signal transmission structure comprises a plurality of pairs of differential signal sources, comprising the steps of:
selecting a first DC voltage level of a first pair of differential signal sources to serve as a first differential signal, wherein the first pair of differential signal sources generates a first data bit;
selecting a second DC voltage level of a second pair of differential signal sources to serve as a second differential signal, wherein the second pair of differential signal sources generates a second data bit;
selecting a third DC voltage level of a third pair of differential signal sources to serve as a third differential signal, wherein the third pair of differential signal sources generate a third data bit;
selecting a fourth DC voltage level of a fourth pair of differential signal sources to serve as a fourth differential signal, wherein the fourth pair of differential signal sources generate a fourth data bit;
generating a fifth data bit according to the first differential signal and the second differential signal;
generating a sixth data bit according to the third differential signal and the fourth differential signal;
generating a seventh data bit according to a fifth DC voltage level of the first differential signal and the second differential signal and a sixth DC voltage level of the third differential signal and the fourth differential signal.

6. The method of claim 5, wherein the fifth data bit is set to a logic level ‘0’ when the first DC voltage level is higher than the second DC voltage level and the fifth data bit is set to a logic level ‘1’ when the first DC voltage level is lower than the second DC voltage level.

7. The method of claim 5, wherein the sixth data bit is set to a logic level ‘0’ when the third DC voltage level is higher than the fourth DC voltage level and the sixth data bit is set to a logic level ‘1’ when the third DC voltage level is lower than the fourth DC voltage level.

8. The method of claim 5, wherein the seventh data bit is set to a logic level ‘0’ when the fifth DC voltage level is higher than the sixth DC voltage level and the seventh data bit is set to a logic level ‘1’ when the fifth DC voltage level is lower than the sixth DC voltage level.
